(19) United States
(12) Patent Application Publication
(10) Pub. No.: US 2025/0013262 A1
(43) Pub. Date: Jan. 9, 2025

(54) HEATING MODULE FOR ELECTRONIC DEVICE DOCK AND METHODS OF MAKING AND USING

(71) Applicant: National Products, Inc., Seattle, WA (US)

(72) Inventors: Jeffrey D. Carnevali, Seattle, WA (US); Scott Anderson, Seattle, WA (US)

(21) Appl. No.: 18/218,381

(22) Filed: Jul. 5, 2023

(51) Int. Cl. G06F 1/16; B60R 11/02; H05K 7/20

(52) U.S. Cl. CPC G06F 1/1632; B60R 11/0252; H05K 7/20172

(57) ABSTRACT

A dock for an electronic device includes a base configured to fit over at least a portion of a back surface of the electronic device, the base including a back surface and defining a first opening through the base; a tray extending from the base; and a heater module coupled, or coupleable, to the back surface of the base over the first opening. The heater module includes a fan to draw air to generate an air flow through the first opening of the base, a heating element to heat the drawn air, a temperature sensor coupled, or coupleable, to the base to monitor a temperature of the dock, the electronic device, or the heated air, and a processor configured to turn the fan and the heating element on or off in response to a temperature monitored by the temperature sensor.

The present invention is directed to heating module for a dock for an electronic device. The present invention is also directed to a dock for an electronic device with a heating module.

### BACKGROUND

Electronic devices, such as tablets, mobile phones, personal data assistants, or the like, are sensitive to temperature. When the ambient or device temperature is too hot or cold, an electronic device may shut down, operate slowly, or fail to perform. The ideal operating temperature range of electronic devices often fall outside of the temperature range in environments in which the electronic devices are intended to be used. For example, such electronic devices may be used in ambient or device temperatures that are at or below 0° C. (32° F.) or at or above 37° C. (approximately 100° F.), for example, in a vehicle sitting in the sun. These temperatures are typically outside the recommended operating temperature range of most electronic devices. An electronic device may operate at such temperatures for extended periods of time.

### BRIEF SUMMARY

One embodiment is a dock for an electronic device. The dock includes a base configured to fit over at least a portion of a back surface of the electronic device when the electronic device is received in the dock, the base including a back surface and defining a first opening through the base; a tray extending from the base for receiving one side of the electronic device; and a heater module coupled, or coupleable, to the back surface of the base over the first opening. The heater module includes a fan to draw air to generate an air flow through the first opening of the base, a heating element to heat the drawn air, a temperature sensor coupled, or coupleable, to the base to monitor a temperature of the dock, the electronic device, or the heated air, and a processor coupled to the fan, the heating element, and the temperature sensor, wherein the processor is configured to turn the fan and the heating element on or off in response to a temperature monitored by the temperature sensor.

In at least some embodiments, the dock further includes a switch, coupled to the processor, to indicate when the electronic device is received in the dock, wherein the processor is configured to only turn on the heating element and the fan when the switch indicates that the electronic device is received in the dock. In at least some embodiments, the switch is configured to engage the electronic device when the heater module is coupled to the back surface of the base and the electronic device is received in the dock.

In at least some embodiments, the temperature sensor includes a thermistor. In at least some embodiments, the base includes at least one second opening through the base for allowing air flow out of the dock including when the fan of the heater module is in operation.

In at least some embodiments, the processor is configured to turn on the fan and the heating element when the temperature sensor indicates a temperature at or below a predefined on-temperature threshold that is in a range of −5 to 5 degrees Celsius. In at least some embodiments, the processor is configured to turn off the fan and the heating element when the temperature sensor indicates a temperature at or above a predefined off-temperature threshold that is in a range of −5 to 5 degrees Celsius. In at least some embodiments, the predefined on-temperature threshold is different from the predefined off-temperature threshold.

In at least some embodiments, the heater module includes a power cord electrically coupled to the fan, heating element, the temperature sensor, and the processor. In at least some embodiments, the heater module is configured for hardwiring to a power source.

Another embodiment is a system that includes any of the docks described above and the electronic device. In at least some embodiments, the system further includes a vehicle, wherein the dock is disposed within the vehicle and the heater module is electrically coupled, or coupleable, to the vehicle.

A further embodiment is a heater module configured for coupling to a dock for receiving an electronic device. The heater module includes a fan to draw air to generate an air flow through an opening in the dock; a heating element to heat the drawn air; a temperature sensor coupleable to the dock to monitor a temperature of the dock, the electronic device, or the heated air; and a processor coupled to the fan, the heating element, and the temperature sensor, wherein the processor is configured to turn the fan and the heating element on or off in response to the temperature monitored by the temperature sensor.

In at least some embodiments, the heater module further includes a switch, coupled to the processor, to identify when the electronic device is received in the dock, wherein the processor is configured to only turn on the heating element and the fan when the switch identifies that the electronic device is received in the dock. In at least some embodiments, the processor is configured to turn on the fan and the heating element when the temperature sensor indicates a temperature at or below a predefined on-temperature threshold that is in a range of −5 to 5 degrees Celsius.

Another embodiment is a method for cooling or heating an electronic device disposed in any of the docks described above. The method includes providing the dock with the heater module coupled to base of the dock; receiving the electronic device in the dock; and heating the dock and electronic device using air heated by the heater module.

In at least some embodiments, the heating includes turning on the fan and the heating element when the temperature sensor indicates a temperature at or below a predefined on-temperature threshold. In at least some embodiments, the method further includes turning off the fan and the heating element when the temperature sensor indicates a temperature at or above a predefined off-temperature threshold.

In at least some embodiments, the heater module further includes a switch, coupled to the processor, to identify when the electronic device is received in the dock, wherein the heating includes only turning on the heating element and the fan when the switch identifies that the electronic device is received in the dock. In at least some embodiments, the receiving includes engaging the switch as the electronic device is received in the dock.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified.

For a better understanding of the present invention, reference will be made to the following Detailed Description, which is to be read in association with the accompanying drawings, wherein:

FIG. 1A is a schematic perspective back view of an embodiment of a dock and a heater module, according to the invention;

FIG. 1B is a schematic perspective front view of the dock and heater module of FIG. 1A, according to the invention;

FIG. 2A is a schematic perspective back view of one embodiment of a heater module, according to the invention;

FIG. 2B is a schematic perspective front view of the heater module of FIG. 2B, according to the invention;

FIG. 2C is a schematic perspective back view of the interior of the heater module of FIG. 2B, according to the invention;

FIG. 2D is a schematic perspective sectional side view of a portion of the heater module of FIG. 2B, according to the invention;

FIG. 2E is a schematic perspective front view of the heater module of FIG. 2B with a portion of the housing removed, according to the invention;

FIG. 2F is a schematic block diagram of operative elements of the heater module of FIG. 2B connected to a power source, according to the invention; and

FIG. 3 is a schematic front view of another embodiment of a dock with an electronic device disposed in the dock, according to the invention.

### DETAILED DESCRIPTION

The present invention is directed to heating module for a dock for an electronic device. The present invention is also directed to a dock for an electronic device with a heating module.

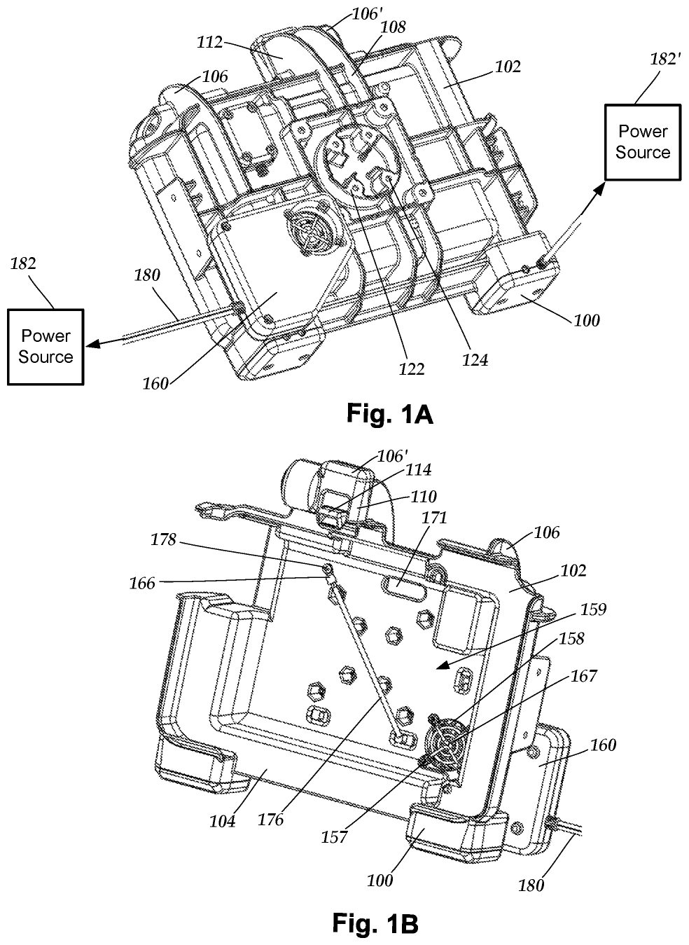

To heat or cool an electronic device, a dock can include a heater module. As illustrated in FIGS. 1A and 1B, one embodiment of a dock 100 includes a base 102, a tray 104 extending from a base 102, and a heater module 160 attached, or attachable, to the base. The tray 104 receives one side of an electronic device 150 (FIG. 3), such as a mobile device (for example, a mobile phone, tablet, personal data assistant, or the like) or a laptop. Examples of docks that can be modified to include an air flow arrangement can be found in, for example, U.S. Pat. Nos. 7,573,706; 7,894,180; 8,179,672; 9,036,343; 9,831,904; 11,029,731; 11,076,032; 11,277,506; 11,489,350; and 11,652,326 and U.S. Patent Application Publications Nos. 2022/0253097 and 2023/0045485, all of which are incorporated by reference in their entireties.

In at least some embodiments, an electronic device 150, such as a mobile device, may be disposed within a cover 152. In at least some embodiments, the dock 102 includes one or more contacts disposed in the tray 104 and configured to couple to contacts on the cover 152 or electronic device 150. Examples of covers 152 for an electronic device 150 are described in U.S. Pat. Nos. 9,195,279; 9,331,444; 9,529,387; 9,602,639; 9,632,535; 9,706,026; 10,389,399; 10,050,658; 10,054,984; 10,454,515; 10,630,334; 10,666,309; 10,778,275 10,812,643; 11,029,731; 11,076,032; 11,165,458; 11, 277,506; and 11,289,864 and U.S. Patent Applications Publication Nos. 2021/0391678 and 2021/0392773, all of which are incorporated herein by reference in their entireties.

In at least some embodiments, the dock 100 also includes at least one attachment arm 106, 106′ extending from the base 102 for attaching the dock to the electronic device 150. Each attachment arm 106, 106′ has a back engagement portion 108, a front engagement portion 110, and a width portion 112 extending between the back and front engagement portions. In at least some embodiments, the back and front engagement portions 108, 110 are arranged to fit snugly on the electronic device 150 disposed therein to retain the electronic device in the dock 100. In at least some embodiments, the front engagement portion 110 of an attachment arm 106′ includes a roller 114 which can roll on an axle held by two legs to facilitate retention of the electronic device 150 within the dock 100.

In at least some embodiments, the dock 100 can have attached, or attachable, to one or more accessories, such as a mount. The mount can be attached to a mounting arrangement 122 on the dock 100 which includes multiple attachment apertures 124 for receiving a fastener to attach the mount to the mounting arrangement. Non-limiting examples of mounts and mounting devices can be found at, for example, U.S. Pat. Nos. 5,845,885; 6,561,476; 7,320,50; 7,997,554; 8,454,178; 8,505,861; 9,831,904; RE42,060; RE42,581; and RE43,806, all of which are incorporated herein by reference in their entireties.

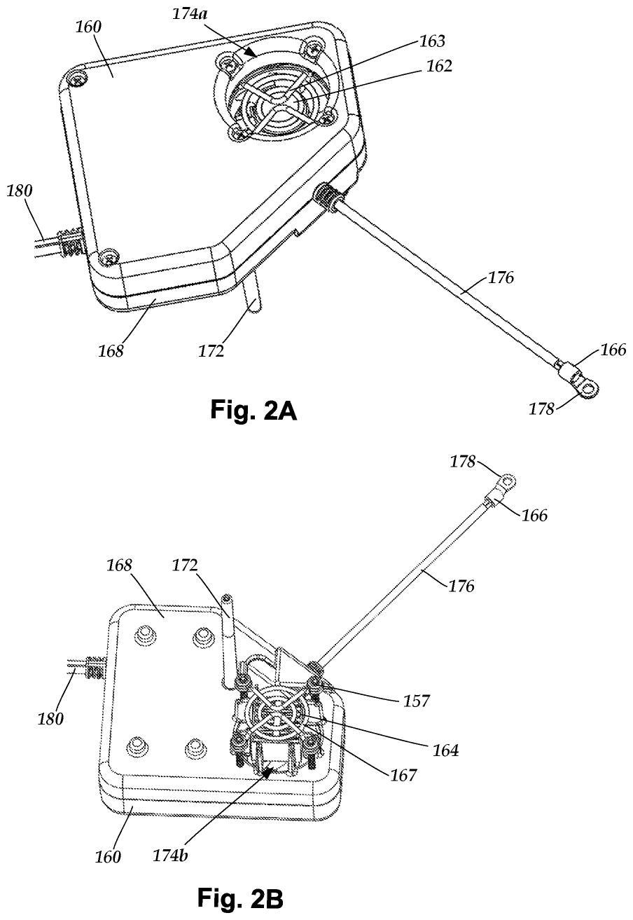

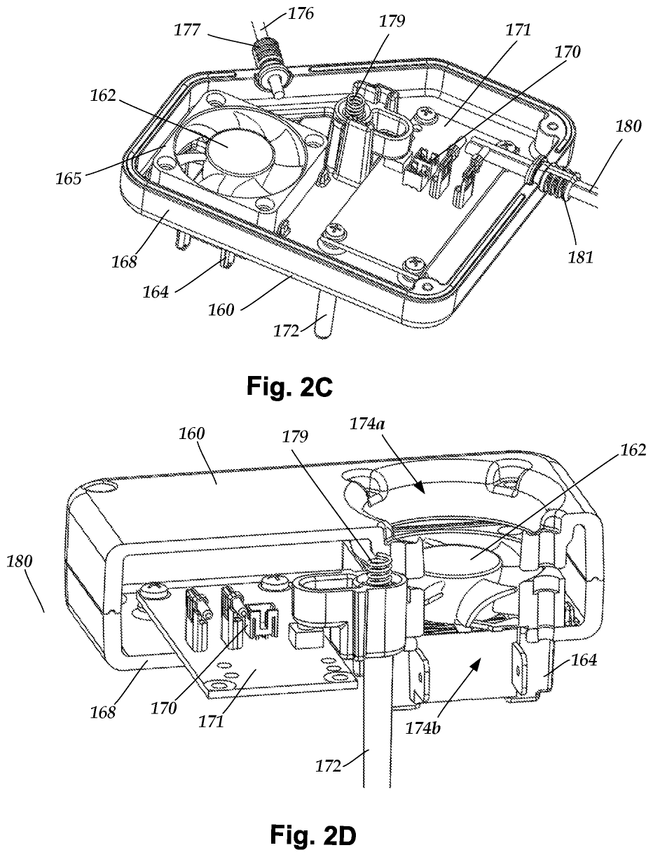

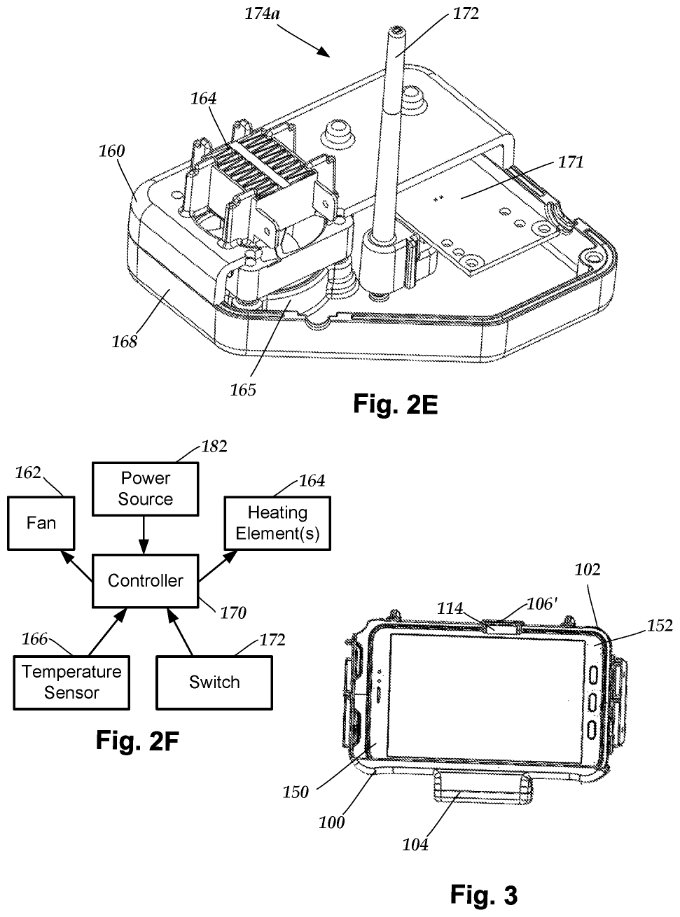

FIGS. 2A to 2F illustrate one embodiment of the heater module 160. This embodiment of the heater module 160 includes a fan 162, at least one heating element 164, a temperature sensor 166, a housing 168, a controller 170, and an optional switch 172. In at least some embodiments, the fan 162 is disposed in a fan housing 165 which is attached or otherwise secured to the housing 168. In at least some embodiments, the fan 162 is a 12-VDC axial cooling fan. The controller 170 controls operation of the fan 162 and heating element(s) 164 and is coupled to the temperature sensor 166. In at least some embodiments, the controller 170 (and, optionally, other components) are disposed on a substrate 171.

The heater module 160 can include a cord 180 for coupling to a power source 182 or to the dock 100 (for example, in some embodiments, in which the dock is coupled to a power source 182′). In at least some embodiments, the cord 180 includes a connector for connecting to a power source. In at least some embodiments, the cord 180 is arranged for hardwiring to a power source. In at least some embodiments, the cord includes a strain relief element 181 provided at the junction with the housing 168.

The housing 168 includes opposing openings 174a, 174b. The fan 162 is disposed within the housing 168 between the opposing openings 174a, 174b. In at least some embodiments, a grill 163 is disposed over the opening 174a to protect the fan and user. In at least some embodiments (including the illustrated embodiment), the heating element(s) 164 is/are disposed outside the housing 168 over the opening 174b. In other embodiments, one or more of the heating element(s) 164 is/are disposed within the housing 168 between the fan 162 and the opening 174b. In at least some embodiments, one or more of the heating element(s) 164 is/are disposed over the opening 174a to heat air drawn by the fan 162 (although this arrangement may be less suitable due to the possibility of user contact with the heating element(s)).

Air is pulled through the opening 174a by the fan 162. The air then passes through the opening 174b and is heated by the heating element(s) 164 (or in other embodiments with different positioning of the heating element(s), heated prior to passing through the opening 174b or through the opening 174a).

The base 102 of the dock 100 includes an opening 158 (FIG. 1B) with the heater module 160 disposed over this opening 158 the base so that the heated air passes through the opening 158 into the cavity 159 of the dock and between the base 102 and the electronic device 150. In at least some embodiments, the base 102 of the dock 100 includes one or more openings 161 for exit of air from the cavity 159.

In at least some embodiments, a grill 167 is disposed over the opening 158. In at least some embodiments, the heater module 160 includes fasteners 157, such as screws, bolts, pins, or the like, that attach the heater module to the base 102 of the dock 100. The base 102 and heater module include openings for passage of the fasteners and, at least in some embodiments, the openings are threaded for attachment of a screw. In at least some embodiments, a grill 167 is disposed over the opening 158 in the base 102 of the dock 100. In at least some embodiments, the fasteners 157 also fasten the grill 167 to the base 102.

In at least some embodiments, the heater module 160 includes a temperature sensor 166, such as a thermistor or any other suitable temperature sensor. In the illustrated embodiment, the temperature sensor 166 is disposed at a distal end portion of a cable 176 with a fastening arrangement 178. In the illustrated embodiment, the temperature sensor 166 is attached to the base 102 using the fastening arrangement 178. Any suitable fastening arrangement 178 can be used including, as illustrated in the Figures, a loop that can be attached to the base 102 using a screw or other fastener, where the screw or other fastener is provided with the heater module 160 or with the dock 100. The length of the cable 176 can be selected to position the temperature sensor 166 at a selected position on the base 102 of the dock 100. In at least some embodiments, the temperature sensor 166 is positioned relatively far from the heater module 160 to measure a temperature relatively far from the heater module. In at least some embodiments, the cable 176 includes a strain relief element 177 at the junction of the cable with the housing 168.

The temperature sensor 166 is coupled to the controller 170 which makes temperature measurements to determine when to turn on or turn off the fan 162 and heating element(s) 164. In at least some embodiments, there is an on-threshold temperature and an off-threshold temperature, which may be the same temperature or may be different temperatures. In at least some embodiments, the off-threshold temperature is higher than the on-threshold temperature. When the heating element(s) 164 and fan 162 are turned off and the temperature measure is at or below the on-threshold temperature, then the controller 170 turns on the heating element(s) 164 and the fan 162. When the heating element(s) 164 and fan 162 are turned on and the temperature measure is at or above the off-threshold temperature, then the controller 170 turns off the heating element(s) 164 and the fan 162. In at least some embodiments, the heating element(s) 164 may be turned off before the fan 162 to facilitate cooling the heating element(s). In at least some embodiments, one or both of the off-threshold temperature and the on-threshold temperature is selected to be a temperature in a range of −5 to +5 degrees Celsius (e.g., 23 to 41 degrees fahrenheit) or −3 to +3 degrees Celsius (e.g., 27 to 37 degrees fahrenheit) or to be 0 degrees Celsius (e.g., 32 degrees fahrenheit).

In at least some embodiments, the heater module 160 includes a switch 172 that identifies when the electronic device 150 is in the dock 100. In the illustrated embodiment, the switch 172 is a plunger switch which engages the electronic device 150 when the electronic device is inserted into the dock. In at least some embodiments, the switch 172 is biased to an open position by, for example, a spring 179 or other biasing element. Any other suitable type of switch 172 can be used including, but not limited to, a manual switch on the heater module 160 or dock 100 that a user can operate or a software switch as part of the dock 100, heater module 160; electronic device 150 that a user can operate through the electronic device; or the like or any other suitable switch arrangement.

In operation, when the switch 172 indicates that the electronic device 150 is inserted into the dock (e.g., the switch 172 is in a closed position), the controller 170 operates the fan 162 and heating element(s) 164 to provided heated air as needed. When the switch 172 indicates that no electronic device 150, the controller 170 prevents operation of the fan 162 and the heating element 164.

The above specification provides a description of the manufacture and use of the invention. Since many embodiments of the invention can be made without departing from the spirit and scope of the invention, the invention also resides in the claims hereinafter appended.

What is claimed as new and desired to be protected by Letters Patent of the United States is:

1. A dock for an electronic device, the dock comprising:
a base configured to fit over at least a portion of a back surface of the electronic device when the electronic device is received in the dock, the base comprising a back surface and defining a first opening through the base;
a tray extending from the base for receiving one side of the electronic device; and
a heater module coupled, or coupleable, to the back surface of the base over the first opening, the heater module comprising
a fan to draw air and generate an air flow through the first opening of the base,
a heating element to heat the drawn air,
a temperature sensor coupled, or coupleable, to the base to monitor a temperature of the dock, the electronic device, or the heated air, and
a processor coupled to the fan, the heating element, and the temperature sensor, wherein the processor is configured to turn the fan and the heating element on or off in response to a temperature monitored by the temperature sensor.

2. The dock of claim 1, further comprising a switch, coupled to the processor, to indicate when the electronic device is received in the dock, wherein the processor is configured to only turn on the heating element and the fan when the switch indicates that the electronic device is received in the dock.

3. The dock of claim 2, wherein the switch is configured to engage the electronic device when the heater module is coupled to the back surface of the base and the electronic device is received in the dock.

4. The dock of claim 1, wherein the temperature sensor comprises a thermistor.

5. The dock of claim 1, wherein the base comprises at least one second opening through the base for allowing air flow out of the dock including when the fan of the heater module is in operation.

6. The dock of claim 1, wherein the processor is configured to turn on the fan and the heating element when the temperature sensor indicates a temperature at or below a predefined on-temperature threshold that is in a range of −5 to 5 degrees Celsius.

7. The dock of claim 6, wherein the processor is configured to turn off the fan and the heating element when the temperature sensor indicates a temperature at or above a predefined off-temperature threshold that is in a range of −5 to 5 degrees Celsius.

8. The dock of claim 7, wherein the predefined on-temperature threshold is different from the predefined off-temperature threshold.

9. The dock of claim 1, wherein the heater module comprises a power cord electrically coupled to the fan, heating element, the temperature sensor, and the processor.

10. The dock of claim 1, wherein the heater module is configured for hardwiring to a power source.

11. A system comprising:
the dock of claim 1; and
the electronic device.

12. The system of claim 11, further comprising a vehicle, wherein the dock is disposed within the vehicle and the heater module is electrically coupled, or coupleable, to the vehicle.

13. A heater module configured for coupling to a dock for receiving an electronic device, the heater module comprising:
a fan to draw air and generate an air flow through the first opening of the base;
a heating element to heat the drawn air;
a temperature sensor coupleable to the dock to monitor a temperature of the dock, the electronic device, or the heated air; and
a processor coupled to the fan, the heating element, and the temperature sensor, wherein the processor is configured to turn the fan and the heating element on or off in response to the temperature monitored by the temperature sensor.

14. The heater module of claim 13, further comprising a switch, coupled to the processor, to identify when the electronic device is received in the dock, wherein the processor is configured to only turn on the heating element and the fan when the switch identifies that the electronic device is received in the dock.

15. The heater module of claim 13, wherein the processor is configured to turn on the fan and the heating element when the temperature sensor indicates a temperature at or below a predefined on-temperature threshold that is in a range of −5 to 5 degrees Celsius.

16. A method for cooling or heating an electronic device disposed in the dock of claim 1, the method comprising:
providing the dock with the heater module coupled to base of the dock;
receiving the electronic device in the dock; and
heating the dock and electronic device using air heated by the heater module.

17. The method of claim 16, wherein the heating comprises turning on the fan and the heating element when the temperature sensor indicates a temperature at or below a predefined on-temperature threshold.

18. The method of claim 17, further comprising turning off the fan and the heating element when the temperature sensor indicates a temperature at or above a predefined off-temperature threshold.

19. The method of claim 16, wherein the heater module further comprises a switch, coupled to the processor, to identify when the electronic device is received in the dock, wherein the heating comprises only turning on the heating element and the fan when the switch identifies that the electronic device is received in the dock.

20. The method of claim 19, wherein the receiving comprises engaging the switch as the electronic device is received in the dock.
